(19) United States
(12) Patent Application Publication
(10) Pub. No.: US 2026/0310139 A1
(43) Pub. Date: Oct. 8, 2026

(54) TIME-TO-DIGITAL CONVERTER AND PHASE-LOCKED LOOP CIRCUIT

(71) Applicant: NOVATEK MICROELECTRONICS CORP., Hsinchu (CN)

(72) Inventors: Chung-Chih Hung, Hsinchu City (CN); Min-Yan Hsieh, Hsinchu County (CN); Yi-Hsun Tsai, Nantou County (CN); Ting-Hsuan Chu, Chiayi County (CN); Tzu-Ting Yang, Kaohsiung City (CN)

(21) Appl. No.: 19/381,654

(22) Filed: Nov. 6, 2025

Related U.S. Application Data
(60) Provisional application No. 63/784,992, filed on Apr. 8, 2025.

(30) Foreign Application Priority Data
Aug. 4, 2025 (CN) 2025110805185

(51) Int. Cl. G04F 10/00; H03L 7/085

(52) U.S. Cl. CPC G04F 10/005; H03L 7/085

(57) ABSTRACT

The present disclosure provides a time-to-digital converter and a phase-locked loop circuit for converting a time difference between a first signal and a second signal into a digital code, including a time-to-voltage conversion module and an analog-to-digital conversion module. The time-to-voltage conversion module includes a current source, a control switch, and a capacitor bank, wherein the control switch is configured to control the current source to charge and discharge the capacitor bank to generate a voltage proportional to the time difference, in response to the first signal, and the analog-to-digital conversion module is configured to sample a voltage across the capacitor bank and convert the voltage into a multi-bit digital code, in response to the second signal.

### CROSS-REFERENCE TO RELATED APPLICATION

The present disclosure claims the benefit of U.S. Provisional Patent application No. 63/784,992, filed on Apr. 8, 2025, and entitled “Charge Pump-Based Time-to-Digital Converter Technology Used in Digital Phase Locked Loops,” and co-pending Chinese Patent Application No. 202511080518.5, filed on Aug. 4, 2025, and entitled “TIME-TO-DIGITAL CONVERTER AND PHASE-LOCKED LOOP CIRCUIT,” the contents of which are incorporated in full by reference herein.

### TECHNICAL FIELD

The present disclosure relates to a time-to-digital converter and a phase-locked loop circuit.

### BACKGROUND

A Time-to-Digital Converter (TDC) is used to convert the time difference between two signals into a digital code. A TDC usually includes a slope voltage generator and an Analog-to-Digital Converter (ADC). The slope voltage generator converts the time difference between two signals into a voltage, and then the ADC converts the voltage into a digital code.

However, the existing slope voltage generators implement the conversion of the time difference between two signals into a voltage by a way of charging and discharging method of an RC circuit, but the linearity of the converted voltage is poor, thereby the accuracy of the generated digital code is also low.

### SUMMARY

Embodiments of the present disclosure provide a time-to-digital converter and a phase-locked loop circuit, which can convert the time difference between two signals into a digital code with high accuracy.

An embodiment of the present disclosure provides a time-to-digital converter for converting the time difference between a first signal and a second signal into a digital code, comprising: a time-to-voltage conversion module, comprising a current source, a control switch, and a capacitor bank, wherein the control switch is configured to control, in response to the first signal, the current source to charge and discharge the capacitor bank to generate a voltage proportional to the time difference; and an analog-to-digital conversion module, configured to sample a voltage across the capacitor bank and converts the voltage into a multi-bit digital code in response to the second signal.

An embodiment of the present disclosure provides a phase-locked loop circuit, comprising: a time-to-digital converter configured to detect the time difference between a first signal and a second signal and output a corresponding multi-bit digital code, wherein the first signal is the feedback pulse signal of the phase-locked loop circuit, and the second signal is the reference pulse signal; a digital-controlled oscillator configured to adjust the frequency of an output clock signal according to the multi-bit digital code; and a feedback path configured to generate the feedback pulse signal based on the output clock signal.

### BRIEF DESCRIPTION OF DRAWINGS

FIG. 1 is a schematic diagram of a circuit block of a time-to-digital converter provided according to an embodiment of the present disclosure;

FIG. 2A is a schematic diagram of a circuit block of a time-to-digital converter in the case of two capacitor banks provided by an embodiment of the present disclosure.

FIG. 2B is a schematic diagram of a circuit block of a time-to-digital converter in the case of one capacitor bank provided by an embodiment of the present disclosure.

FIG. 3 is a timing relationship diagram of the first/second signals and the corresponding charge/discharge curves provided by an embodiment of the present disclosure;

FIG. 4 is a schematic diagram of a circuit block of a time-to-digital converter provided by another embodiment of the present disclosure;

FIG. 5 is a schematic diagram of a circuit block of a phase-locked loop circuit provided by an embodiment of the present disclosure.

### LIST OF REFERENCE NUMERALS

FEED: First signal

REF: Second signal

100, 200A, 200B, 400, 500: Time-to-digital converter

110, 210A, 210B, 410: Time-to-voltage conversion module

120, 220A, 220B, 420: Analog-to-digital conversion module

111, 211A, 211B, 411: Current source

112, 212A, 212B, 412: Control switch

113, 213A, 213B, 413: Capacitor bank

221A, 221B, 421: Time-voltage conversion control switch

111, 211A_a, 211B_a, 411_a: First current source

111, 211A_b, 411_b: Second current source

212A_a, 212B_a, 412_a: First switch

212A_b, 412_b: Second switch

212A_c, 212B_c, 412_c: Third switch

212A_d, 412_d: Fourth switch

213A_a, 213B_a, 413_a: First capacitor bank

213A_b, 413_b: Second capacitor bank

221A_a, 221B_a, 421_a: First conversion control switch

221A_b, 421_b: Second conversion control switch

222A, 222B: Analog-to-digital conversion device

422: Capacitor switching switch group

422_a: First capacitor switching switch group

422_b: Second capacitor switching switch group

423: Switch control module

600: Digital-controlled oscillator

700: Feedback path

810: Frequency divider

900: Loop filter

1000: Phase-locked loop circuit

### DETAILED DESCRIPTION

Reference will now be made in detail to the exemplary embodiments of the present disclosure, examples of which are illustrated in the accompanying drawings. Wherever possible, the same reference numerals are used in the drawings and the description to refer to the same or like parts.

The term “coupled (or connected)” used throughout the specification of the present disclosure (including the claims) may refer to any direct or indirect connection means. For example, if it is described in the text that a first device is coupled (or connected) to a second device, it should be interpreted that the first device may be directly connected to the second device, or the first device may be indirectly connected to the second device through other devices or some connection means. Terms such as “first” and “second” mentioned throughout the specification of the present disclosure (including the claims) are used to name components (elements) or to distinguish different embodiments or scopes, rather than to limit the upper or lower limit of the number of components, nor to limit the order of the components. In addition, wherever possible, components/members/steps with the same reference numerals in the drawings and embodiments represent the same or similar parts. Components/members/steps with the same reference numerals or using the same terms in different embodiments can refer to the relevant descriptions.

In the traditional slope voltage generator, the RC circuit is charged and discharged. During the charging and discharging process, the voltage across the capacitor has a time-voltage nonlinear characteristic, which makes it impossible to accurately convert the time difference into a linearly proportional voltage, resulting in insufficient accuracy of the digital code of the voltage and ultimately affecting the accuracy of the conversion result.

Based on this, an embodiment of the present disclosure provides a time-to-digital converter 100. The time-to-digital converter 100 can convert the time difference between the first signal FEED and the second signal REF into an accurate digital code.

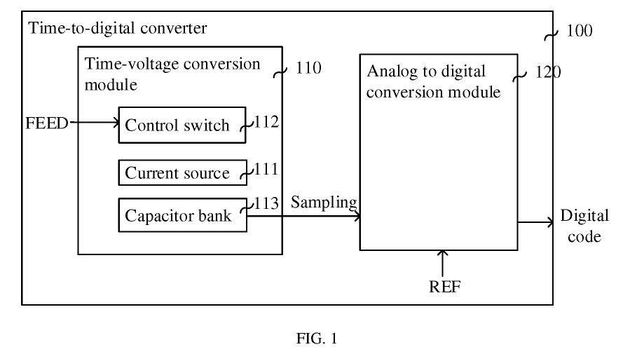

FIG. 1 is a schematic diagram of a circuit block of a time-to-digital converter (TDC) 100 according to an embodiment of the present disclosure. As shown in FIG. 1, the time-to-digital converter 100 includes a time-to-voltage conversion module 110 and an analog-to-digital conversion module 120. The time-to-voltage conversion module 110 includes a current source 111, a control switch 112, and a capacitor bank 113. The control switch 112 controls the current source 111 to charge and discharge the capacitor bank 113, in response to the first signal FEED, to generate a voltage proportional to the time difference. The analog-to-digital conversion module 120 samples a voltage across the capacitor bank 113 and converts the voltage into a multi-bit digital code in response to the second signal REF.

In this embodiment, when the first signal FEED arrives, the current source 111 is triggered to charge and discharge the capacitor bank 113 to generate a charging and discharging curve; and when the second signal REF arrives, the generated charging and discharging curve is triggered to be sampled and held. In this process, since the arrival time of the second signal REF is different, the sampled and held voltage value also varies accordingly, thereby converting the time difference between the first signal FEED and the second signal REF into a voltage.

According to the embodiments of the present disclosure, since the capacitor bank 113 is charged and discharged through the current source 111 to generate a slope voltage linearly related to time, the time difference between the two signals is proportional to the sampling voltage. This voltage can accurately reflect the time difference between the signals, which can then be converted into a high-precision digital code.

In this embodiment, charging and discharging the capacitor bank 113 may refer to the process of injecting charges into the capacitor bank 113 through the current source 111 and/or releasing charges from the capacitor bank 113 through the current source 111. For example, the charging and discharging may include charging the capacitor bank 113 (injecting charges), discharging the capacitor bank 113 (releasing charges), or charging a first part of the capacitor bank 113 and discharging a second part of the capacitor bank 113.

The first signal FEED can be any pulse signal for which the time difference with the reference signal needs to be measured, such as an external pulse signal to be measured or an internal feedback pulse signal (such as the feedback signal in a phase-locked loop circuit). The second signal REF can be a reference pulse signal, such as the system clock signal. It should be noted that the first signal FEED and the second signal REF are not limited to pulse signals. As long as they are converted into signals that can trigger the current source 111 to charge and discharge the capacitor bank 113 and sample and hold the generated charging and discharging curves through an appropriate conversion circuit, the time-to-digital converter provided by the embodiments of the present disclosure can be used for time difference measurement.

In addition, the time difference can represent the relative timing characteristics between signals, such as the phase difference between two signals. In one embodiment, the phase difference between the two signals can be obtained by measuring the time between the first state transition of the first signal FEED and the first state transition of the second signal REF. The first state transition is not limited to the rising edge, falling edge, or level transition of the signal.

For example, the control switch 112 can control the current source 111 to charge and discharge the capacitor bank 113 in response to the first state transition of the first signal FEED, and generate a voltage proportional to the time difference. Subsequently, the analog-to-digital conversion module 120 stops the current source 111 from charging and discharging the capacitor bank 113 in response to the first state transition of the second signal REF, samples the voltage across the capacitor bank 113, and converts the voltage into a digital code.

In this embodiment, the first state transition of the first signal FEED triggers the generation of a slope voltage, and the first state transition of the second signal REF triggers the sampling of the voltage. Since the corresponding operations are triggered under the same state transitions of the two signals, the time difference between the two signals in the same state can be measured, thereby improving the accuracy of the time difference measurement. At the same time, the slope voltage is always triggered to be generated under the first state transition of the signal, which can ensure that each measurement is carried out under completely consistent initial conditions, thus ensuring the consistency of the time difference measurement results.

According to the embodiments of the present disclosure, the capacitor bank 113 for charge storage and release can have the structure of one capacitor bank or two capacitor banks. There is no limitation on the number of capacitor banks here.

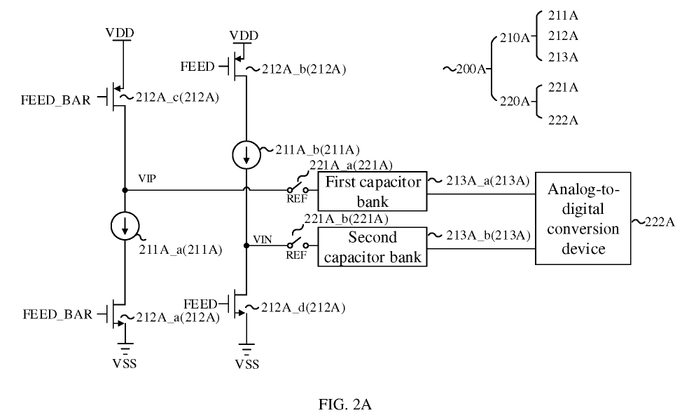

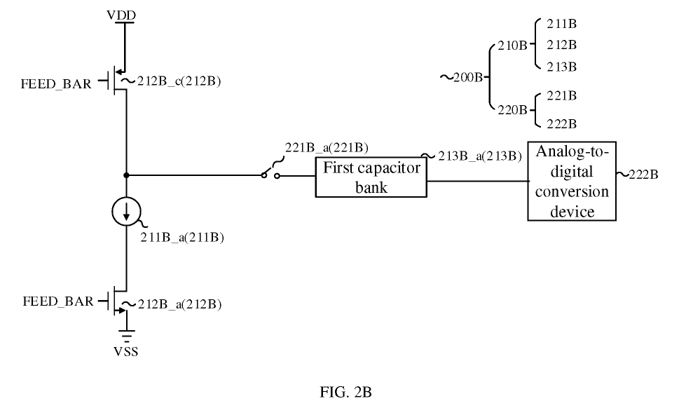

FIG. 2A is a schematic circuit block diagram of a time-to-digital converter in the case of two capacitor banks provided by an embodiment of the present disclosure, which provides a time-to-digital converter 200A based on a differential structure. Since the time-to-voltage conversion module is easily interfered by factors such as external noise and unstable power supply, problems such as non-linear change in the slope of the generated slope voltage and gain change with phase may occur, affecting the accuracy of the sampling results. The time-to-digital converter 200A based on the differential structure can effectively eliminate common-mode interference.

In FIG. 2A, if two components belong to the same part, the marking of the components should be referred to as “X1 (Y)” and “X2 (Y)”, wherein “(Y)” indicates that both components “X1” and “X2” belong to part “Y”. “FEED_BAR” represents the inverse signal of the first signal “FEED.”

As shown in FIG. 2A, the time-to-digital converter 200A includes a voltage conversion module 210A and an analog-to-digital converter module 220A.

The voltage conversion module 210A can include a current source 211A, a control switch 212A, and a capacitor bank 213A. The current source 211A may include a first current source 211A_a and a second current source 211A_b. The control switch 212A may include a first switch 212A_a and a second switch 212A_b. The capacitor bank 213A may include a first capacitor bank 213A_a and a second capacitor bank 213A_b.

The first current source 211A_a is connected in series between the first end of the first capacitor bank 213A_a and the first end of the first switch 212A_a, and the second end of the first switch 212A_a is grounded. The second current source 211A_b is connected in series between the second end of the second switch 212A_b and the first end of the second capacitor bank 213A_b, and the first end of the second switch 212A_b is connected to the power supply voltage. Among them, the first switch 212A_a and the second switch 212A_b are used to control the charging and discharging of the first capacitor bank 213A_a and the second capacitor bank 213A_b by the first current source 211A_a and the second current source 211A_b, respectively. For example, when the initial state of the first capacitor bank 213A_a and/or the second capacitor bank 213A_b is a charged state, the first current source 211A_a and/or the second current source 211A_b are used to discharge the first capacitor bank 213A_a and/or the second capacitor bank 213A_b, respectively. Conversely, when the initial state of the first capacitor bank 213A_a and/or the second capacitor bank 213A_b is a discharged state, the first current source 211A_a and/or the second current source 211A_b are used to charge the first capacitor bank 213A_a and/or the second capacitor bank 213A_b, respectively.

The analog-to-digital conversion module 220A can include a time-to-voltage conversion control switch 221A, and the time-to-voltage conversion control switch 221A can include a first conversion control switch 221A_a and a second conversion control switch 221A_b. The first conversion control switch 221A_a is connected between the first end of the first current source 211A_a and the first end of the first capacitor bank 213A_a, and the second conversion control switch 221A_b is connected between the second end of the second current source 211A_b and the first end of the second capacitor bank 213A_b. The first conversion control switch 221A_a and the second conversion control switch 221A_b are used to turn on/off the conductive paths between the first current source 211A_a and the first capacitor bank 213A_a, and between the second current source 211A_b and the second capacitor bank 213A_b respectively, so as to achieve sampling and holding of the voltage across the capacitor bank.

In addition, the analog-to-digital conversion module 220A may also include an analog-to-digital conversion device 222A, which is used to obtain the corresponding digital voltage code based on the voltages on the first capacitor bank 213A_a and the second capacitor bank 213A_b.

Additionally, according to an embodiment of the present disclosure, the control switch 212A may further include a third switch 212A_c and a fourth switch 212A_d. The first end of the third switch 212A_c is connected to the power supply voltage, and the second end is connected to the first end of the first capacitor bank 213A_a. The first end of the fourth switch 212A_d is connected to the first end of the second capacitor bank 213A_b, and the second end is grounded. The third switch 212A_c and the fourth switch 212A_d are respectively used to control the initialization of the first capacitor bank 213A_a and the second capacitor bank 213A_b. It should be understood that the embodiments of the present disclosure are not limited thereto, and other switches, current sources, or voltage sources may be used to initialize the first capacitor bank 213A_a and the second capacitor bank 213A_b.

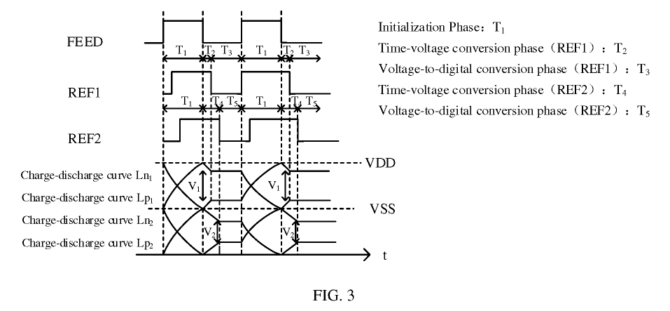

The following describes the workflow of the time-to-digital converter 200A in FIG. 2A with reference to FIG. 3. FIG. 3 shows the timing relationships of various signals and the charge-discharge curves in Case 1 where the first signal is FEED and the second signal is REF1, and in Case 2 where the first signal is FEED and the second signal is REF2. The charge-discharge curves Lp₁/Ln₁ and Lp₂/Ln₂ are the voltage change curves of points VIP and VIN in FIG. 2A in Case 1 and Case 2, respectively. In this embodiment, the workflow of the time-to-digital converter 200A can be divided into an initialization phase T1, a time-to-voltage conversion phase T2/T4 (corresponding to Case 1/Case 2, respectively), and a voltage-to-digital code conversion phase T3/T5 (corresponding to Case 1/Case 2, respectively). The following describes each phase.

### Initialization phase T1

As shown in FIG. 2A, in the initialization phase, in response to the second state transition of the first signal FEED (in this embodiment, the second state transition is assumed to be the high-level period of the signal), the third switch 212A_c is turned on, and the first capacitor bank 213A_a is discharged to be initialized to a discharged state, and the fourth switch 212A_d is turned on, and the second capacitor bank 213A_b is charged to be initialized to a charged state. Thus, the possible residual historical charges in the capacitor banks can be cleared, and the influence of the previous working state on the current measurement result can be avoided, thereby improving the accuracy and stability of the measurement.

In FIG. 3, during the high-level period (Phase T1) of the first signal FEED, the third switch 212A_c is turned on, and the first capacitor bank 213A_a is discharged, increasing the voltage at point VIP to VDD. Meanwhile, the fourth switch 212A_d is turned on, and the second capacitor bank 213A_b is charged, decreasing the voltage at point VIN to VSS.

### Time-to-voltage conversion phase T2/T4

As shown in FIG. 2A, in response to the first state transition of the first signal FEED (in this embodiment, the first state transition is assumed to be the falling edge of the signal), the first switch 212A_a and the second switch 212A_b are turned on respectively, so that the first current source 211A_a charges the first capacitor bank 213A_a, and the second current source 211A_b discharges the second capacitor bank 213A_b.

In FIG. 3, during the T2/T4 phase, in response to the falling edge of the first signal FEED, the first switch 212A_a is turned on, and the first capacitor bank 213A_a is charged, causing the voltage at the VIP point to linearly decrease from VDD. Meanwhile, the second switch 212A_b is turned on, and the second capacitor bank 213A_b is discharged, causing the voltage at the VIN point to linearly increase from VSS.

### Voltage-to-digital code conversion phase T3/T5

As shown in FIG. 2A, in response to the first state transition of the second signal REF, the first conversion control switch 221A_a and the second conversion control switch 221A_b respectively disconnect the conductive path between the first current source 211A_a and the first capacitor bank 213A_a, and the conductive path between the second current source 211A_b and the second capacitor bank 213A_b. Thus, the charges on the first capacitor bank 213A_a and the second capacitor bank 213A_b are sampled and held to form a voltage difference.

In FIG. 3, in response to the falling edge of the second signal REF1, the first conversion control switch 221A_a and the second conversion control switch 221A_b disconnect the conductive path between the first current source 211A_a and the first capacitor bank 213A_a, and the conductive path between the second current source 211A_b and the second capacitor bank 213A_b, respectively, thereby forming a voltage difference V1. Similarly, a voltage difference V2 is formed when the falling edge of the first signal REF2 arrives. As can be seen from FIG. 3, the phase of the second signal REF1 lags slightly behind that of the first signal FEED, and the sampled voltage difference V1 is relatively large. The phase of the second signal REF2 lags behind that of the first signal FEED more, and the sampled voltage difference V2 is relatively small. Since there is a linear relationship between time and voltage in the charge-discharge curve, the time difference between the two signals can be accurately reflected by the magnitude of the voltage difference.

After obtaining the voltage that can accurately reflect the time difference between the two signals, this voltage can be converted into an accurate digital code by the analog-to-digital conversion module 220A (the process of converting the digital code will be detailed later).

It should be noted that in FIG. 3, the timing of the voltage-to-digital code conversion phase (T3/T5) is defined as starting from the falling edge trigger of the second signal REF and ending when the first signal FEED becomes high. However, the actual duration of the timing can be dynamically adjusted according to the analog-to-digital conversion requirements.

In addition, in the first initialization phase in FIG. 3, the initial voltages at the VIP and VIN points respectively rise from VSS to VDD and fall from VDD to VSS. However, the initial voltage is not limited to VSS or VDD, and it varies depending on the sampled voltage when the first conversion control switch 221A_a and the second conversion control switch 221A_b disconnect the conductive paths of the current source and the voltage source during the voltage-to-digital code conversion phase (T3/T5).

In this embodiment, the time-to-voltage conversion module 210A generates two charge-discharge curves by way of a differential structure. Even if the charge-discharge process is affected by external interference, since the two curves will be affected in the same way under the same interference source, the voltage difference between the two curves can effectively eliminate such common-mode interference. The time-to-digital converter in this embodiment avoids the gain nonlinearity problem in the single-ended structure, improves the accuracy of converting time to voltage, and further enhances the accuracy of digital code conversion.

The above describes the situation where the capacitor bank 213A includes two capacitor banks. However, it should be noted that the number of capacitor banks is not limited to two and can be set to one or more as required. For example, FIG. 2B is a circuit block diagram of a time-to-digital converter with one capacitor bank according to an embodiment of the present disclosure.

As shown in FIG. 2B, the time-to-digital converter 200B includes a voltage conversion module 210B and an analog-to-digital converter module 220B. The voltage conversion module 210B includes a current source 211B, a control switch 212B, and a capacitor bank 213B. The current source 211B may include a first current source 211B_a, the control switch 212B may include a first switch 212B_a, and the capacitor bank 213B may include a first capacitor bank 213B_a. The first current source 211B_a is connected in series between the first end of the first capacitor bank 213B_a and the first end of the first switch 212B_a, and the second end of the first switch 212B_a is grounded. The first switch 212B_a is used to control the first current source 211B_a to charge. The analog-to-digital conversion module 220B may include a time-to-voltage conversion control switch 221B, and the time-to-voltage conversion control switch 221B may include a first conversion control switch 221B_a. The first conversion control switch 221B_a is connected between the first end of the first current source 211B_a and the first end of the first capacitor bank 213B_a.

When the first signal FEED arrives, this signal triggers the first switch 212B_a to close, enabling the first current source 211B_a to charge the first capacitor bank 213B_a and generate a charging curve. When the second signal REF arrives, this signal triggers the first conversion control switch 221B_a to open, and samples and holds the generated charging curve. During this process, since the arrival time of the second signal REF varies, the sampled and held voltage value also changes accordingly, thereby converting the time difference between the first signal FEED and the second signal REF into voltage, and converting and outputting the corresponding digital code through the analog-to-digital conversion device 222B.

In addition, according to an embodiment of the present disclosure, the control switch 212B may further include a third switch 212B_c. The first end of the third switch 212B_c is connected to the power supply voltage, and the second end is connected to the first end of the first capacitor bank 213B_a. When the first capacitor bank 113B_a is initialized to the discharged state through the third switch 212B_c, the first current source 211B_a is used to charge the first capacitor bank 213B_a.

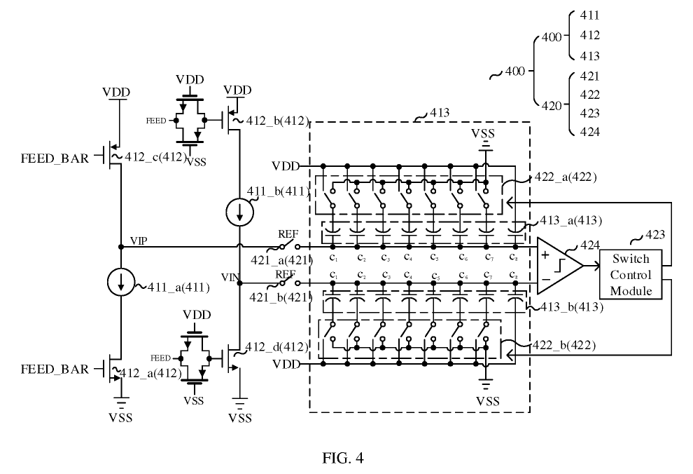

FIG. 4 is a circuit block diagram of a time-to-digital converter according to another embodiment of the present disclosure. In the time-to-voltage conversion module 410, a capacitor bank is required to generate a slope voltage. In the analog-to-digital conversion module 420, a capacitor bank is configured to convert the sampled voltage into a digital code. If each module is configured with its own capacitor bank, the number of devices will increase, and a larger area will be occupied. Therefore, an embodiment of the present disclosure provides a time-to-digital converter 400, in which the time-to-voltage conversion module 410 and the analog-to-digital conversion module 420 share the same capacitor bank 413, thereby reducing the number of devices and the occupied space and improving the integration level.

This embodiment mainly describes the shared capacitor bank 413. The shared capacitor bank 413 includes a first capacitor bank 413_a and a second capacitor bank 413_b. The number of capacitors in the first capacitor bank 413_a is the same as that in the second capacitor bank 413_b, and the capacitors in the two groups are paired one by one. For example, in the embodiment of FIG. 4, both the first capacitor bank 413_a and the second capacitor bank 413_b include 8 capacitors, and the capacitance values of the capacitors from the leftmost side are C1, C2, C3, ... in sequence.

The analog-to-digital conversion module 420 further includes a capacitor switching switch group 422. The capacitor switching switch group 422 includes a first capacitor switching switch group 422_a and a second capacitor switching switch group 422_b. The first ends of the capacitors in the first capacitor bank 413_a (the ends marked with capacitor symbols C1, C2, ... C8 in the figure) are connected to each other. The second end (the opposite end of the first end) of one of the capacitors is connected to the power supply voltage, and the second ends of the other capacitors are controllably connected to the power supply voltage or ground via the corresponding switches in the first capacitor switching switch group 422_a respectively. The first ends of the capacitors in the second capacitor bank 413_b (the ends marked with capacitor symbols C1, C2, ... C8 in the figure) are connected to each other. The second end (the opposite end of the first end) of one of the capacitors is connected to the power supply voltage, and the second ends of the other capacitors are controllably connected to the power supply voltage or ground via the corresponding switches in the second capacitor switching switch group 422_b respectively.

The following describes the shared use of the capacitor bank by the time-to-voltage conversion module 410 and the analog-to-digital conversion module 420. During the process in which the control switch 412 controls the charging and discharging of the capacitor bank 413, it is assumed that the capacitor bank 413 is in the first connection state. During the process in which the analog-to-digital conversion module 420 samples the voltage across the capacitor bank 413 and converts it into a digital code, it is assumed that the capacitor bank 413 is in the configurable second connection state.

In the first connection state, the second end of each capacitor in the first capacitor bank 413_a is connected in parallel to the power supply voltage, and the first end is connected in parallel to the first end of the first current source 411_a. The second end of each capacitor in the second capacitor bank 413_b is connected in parallel to the power supply voltage, and the first end is connected in parallel to the second end of the second current source 411_b.

The analog-to-digital conversion module 420 further includes a switch control module 423, which uses a successive approximation algorithm to generate capacitor switching signals for controlling each pair of switches in the first capacitor switching switch group 422_a and the second capacitor switching switch group 422_b.

In the configurable second connection state, through the control of the first capacitor switching switch group 422_a and the second capacitor switching switch group 422_b by the capacitor switching signals, the first capacitor bank 413_a is divided into a first capacitor subgroup and a second capacitor subgroup, and the first capacitor subgroup and the second capacitor subgroup are connected in series between the power supply voltage and ground. The second capacitor bank 413_b is divided into a third capacitor subgroup and a fourth capacitor subgroup, and the third capacitor subgroup and the fourth capacitor subgroup are connected in series between the power supply voltage and ground.

The analog-to-digital conversion module 420 further includes a comparator 424. The positive input terminal of the comparator 424 is connected to the first ends of the capacitors in the first capacitor bank 413_a, the negative input terminal of the comparator 424 is connected to the first ends of the capacitors in the second capacitor bank 413_b, and output terminal of the comparator 424 outputs a digital code. The comparator 424 is configured to output multiple digital codes constituting a multi-bit digital code by comparisons under the control of the capacitor switching signals generated based on the successive approximation algorithm.

In this embodiment, the number of devices and the occupied space are reduced by sharing the capacitor bank, and the integration degree is improved.

The following takes each capacitor bank including 8 capacitors as an example to describe the specific operations at each stage. For example, the first capacitor bank 413_a and the second capacitor bank 413_b satisfy Cᵢ= 2^{n - i - 1}C₀ (i = 1~n - 1), Cₙ= C₀, wherein “n” is the number of capacitors included in a capacitor bank, and “Cᵢ” represents the capacitance value of the i-th capacitor from left to right. The number of capacitors and the value of “ C₀” can be set as needed, as long as the digital code accuracy requirements are met.

### Initialization stage

The switch control module 423 outputs a capacitor switching signal. In response to this capacitor switching signal, the first capacitor switching switch group 422_a is connected to the power supply voltage, so that the second end of each capacitor in the first capacitor bank 413_a is connected in parallel to the power supply voltage. The first conversion control switch 421_a is turned on, so that the first end is connected in parallel to the first end of the first current source 411_a. In addition, in response to this capacitor switching signal, the second capacitor switching switch group 422_b is connected to the power supply voltage, so that the second end of each capacitor in the second capacitor bank 413_b is connected in parallel to the power supply voltage. The second conversion control switch 421_b is turned on, so that the first end is connected in parallel to the second end of the second current source 411_b.

In response to the second state transition of the first signal FEED, the third switch 412_c is turned on, so that the first capacitor bank 413_a releases charge via the discharge path (i.e., VDD - third switch 412_c - first conversion control switch 421_a - first capacitor bank 413_a - VDD) until the voltage at its first end is equal to the power supply voltage, and thus is initialized to the discharged state; at the same time, the fourth switch 412_d is turned on, so that the second capacitor bank 413_b stores charge via the charging path (i.e., VSS - fourth switch 412_d - second conversion control switch 421_b - second capacitor bank 413_b - VDD) until the voltage at its first end is equal to the ground voltage, and thus is initialized to the charged state.

### Time - voltage conversion stage

The connection states of the switches in the first capacitor switching switch group 422_a and the second capacitor switching switch group 422_b, and the connection states of the first and second ends of the first capacitor bank 413_a and the second capacitor bank 413_b during the initialization stage are maintained.

In response to the first state transition of the first signal FEED, the first switch 412_a is turned on (the third switch 412_c is turned off), so that the first capacitor bank 413_a stores charge via the charging path (i.e., VSS - first switch 412_a - first conversion control switch 421_a - first capacitor bank 413_a - VDD) to generate a charging curve where the time and voltage are linearly related; at the same time, the second switch 412_b is turned on (the fourth switch 412_d is turned off), so that the second capacitor bank 413_b releases charge via the discharge path (i.e., VDD - second switch 412_b - second conversion control switch 421_b - second capacitor bank 413_b - VDD) to generate a discharge curve where the time and voltage are linearly related.

### Voltage-to-digital code conversion stage

In response to the first state transition of the second signal REF, the first conversion control switch 421_a and the second conversion control switch 421_b disconnect the conductive path between the first current source 411_a and the first capacitor bank 413_a, and the conductive path between the second current source 411_b and the second capacitor bank 413_b, respectively. As a result, the charges on the first capacitor bank 413_a and the second capacitor bank 413_b are sampled and held to form a voltage.

At this time, the comparator 424 compares the voltage at the first end of the first capacitor bank 413_a with the voltage at the first end of the second capacitor bank 413_b. If the former is greater than the latter, the first-bit digital code ‘1’ is generated. Meanwhile, the switch control module 423 generates a capacitor switching signal, causing the leftmost switch of the first capacitor switching switch group 422_a to ground the second end of the corresponding capacitor, and causing the leftmost switch of the second capacitor switching switch group 422_b to keep connecting the second end of the corresponding capacitor to the power supply voltage. Conversely, the first-bit digital code ‘0’ is generated. Meanwhile, the switch control module 423 generates a capacitor switching signal to perform the opposite operation, that is, causing the leftmost switch of the first capacitor switching switch group 422_a to keep connecting the second end of the corresponding capacitor to the power supply voltage, and causing the leftmost switch of the second capacitor switching switch group 422_b to ground the second end of the corresponding capacitor.

Then, the comparator 424 compares the voltage at the first end of the first capacitor bank 413_a after capacitor switching with the voltage at the first end of the second capacitor bank 413_b. If the former is greater than the latter, the second-bit digital code ‘1’ is generated. Meanwhile, the switch control module 423 generates a capacitor switching signal, causing the second switch from the left of the first capacitor switching switch group 422_a to ground the second end of the corresponding capacitor, and making the second switch from the left of the second capacitor switching switch group 422_b keep connecting the second end of the corresponding capacitor to the power supply voltage. By analogy, the above operations are repeated to sequentially generate an 8-bit digital code.

After the voltage-to-digital code conversion stage, the initialization stage is entered again.

It should be understood that the 8 capacitors and the 8-bit digital code in FIG. 4 are merely examples. Those skilled in the art can set different numbers of capacitors and corresponding-bit digital codes as needed.

The above describes the operation process of the time-to-digital converter in the case of two capacitor banks with reference to FIGS. 2A, 3, and 4. The operation process of the time-to-digital converter in the case of one capacitor bank is similar. The successive approximation algorithm can be used to generate the capacitor switching signals for controlling each switch, and details are not repeated here.

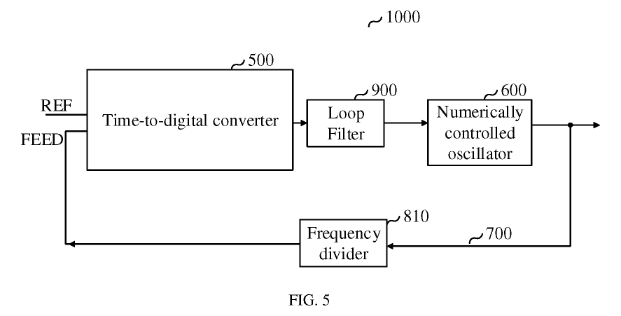

FIG. 5 is a schematic circuit block diagram of a phase-locked loop circuit 1000 provided by an embodiment of the present disclosure. The phase-locked loop circuit 1000 can be used for signal synchronization and frequency adjustment, including a time-to-digital converter 500 for detecting the time difference between the first signal and the second signal REF and outputting a corresponding multi-bit digital code, a digital-controlled oscillator 600 configured to adjust the frequency of its output clock signal according to the multi-bit digital code, and a feedback path 700 configured to generate a feedback pulse signal based on the output clock signal.

The first signal can be the feedback pulse signal of the phase-locked loop circuit, and the second signal REF can be the reference pulse signal.

In one embodiment, the phase-locked loop circuit 1000 further includes a loop filter 900, which is connected between the time-to-digital converter 500 and the digital-controlled oscillator 600 for filtering the multi-bit digital code. Through the loop filter 900, noise and fluctuations can be reduced, thereby improving the stability and accuracy of the phase-locked loop circuit 1000.

In one embodiment, the feedback path 700 includes a frequency divider 810, which is configured to generate a feedback pulse signal after dividing the frequency of the output clock signal. Through the frequency divider 810, the frequency of the output clock signal can be adjusted to ensure that the feedback signal and the reference signal are synchronized under the correct frequency relationship.

For those skilled in the art, various modifications and changes can be made to the disclosed embodiments without departing from the scope or spirit of the present disclosure. In summary, the present disclosure is intended to cover modifications and changes as long as they fall within the scope of the appended claims and their equivalents.

What is claimed is:

1. A time-to-digital converter for converting a time difference between a first signal and a second signal into a digital code, comprising:
a time-to-voltage conversion module, comprising a current source, a control switch, and a capacitor bank, wherein the control switch is configured to control, in response to the first signal, the current source to charge and discharge the capacitor bank to generate a voltage proportional to the time difference; and
an analog-to-digital conversion module configured to sample a voltage across the capacitor bank and convert the voltage into a multi-bit digital code in response to the second signal.

2. The time-to-digital converter according to claim 1, wherein
the control switch is configured to control, in response to a first state transition of the first signal, the current source to charge and discharge the capacitor bank to generate a voltage proportional to the time difference;
the analog-to-digital conversion module is configured to stop, in response to the first state transition of the second signal, the current source from charging and discharging the capacitor bank, sample a voltage across the capacitor bank and convert the voltage into the multi-bit digital code.

3. The time-to-digital converter according to claim 2, wherein
the capacitor bank comprises a first capacitor bank and a second capacitor bank, wherein the first capacitor bank is initialized to a discharged state and the second capacitor bank is initialized to a charged state; and
the current source comprises a first current source and a second current source, and the control switch is configured to control, in response to the first state transition of the first signal, the first current source to charge the first capacitor bank, and control the second current source to discharge the second capacitor bank.

4. The time-to-digital converter according to claim 3, wherein the control switch comprises a first switch and a second switch;
the first current source is connected in series between the first end of the first capacitor bank and the first end of the first switch, and the second end of the first switch is grounded; and
the second current source is connected in series between the second end of the second switch and the first end of the second capacitor bank, and the first end of the second switch is connected to a power supply voltage.

5. The time-to-digital converter according to claim 4, wherein the control switch further comprises a third switch and a fourth switch;
the first end of the third switch is connected to the power supply voltage, and the second end is connected to the first end of the first capacitor bank;
the first end of the fourth switch is connected to the first end of the second capacitor bank, and the second end is grounded.

6. The time-to-digital converter according to claim 3, wherein the analog-to-digital conversion module comprises a time-to-voltage conversion control switch, configured to disconnect, in response to the first state transition of the second signal, the conductive path between the first current source and the first capacitor bank, and the conductive path between the second current source and the second capacitor bank.

7. The time-to-digital converter according to claim 6, wherein the time-to-voltage conversion control switch comprises a first conversion control switch and a second conversion control switch, the first conversion control switch is connected between the first end of the first current source and the first end of the first capacitor bank, and the second conversion control switch is connected between the second end of the second current source and the first end of the second capacitor bank; and
the first conversion control switch is configured to disconnect, in response to the first state transition of the second signal, the conductive path between the first current source and the first capacitor bank, and the second conversion control switch is configured to disconnect, in response to the first state transition of the second signal, the conductive path between the second current source and the second capacitor bank.

8. The time-to-digital converter according to claim 3, wherein, during the process in which the control switch controls the charging and discharging of the capacitor bank, the capacitor bank is in a first connection state; and
during the process in which the analog-to-digital conversion module samples the voltage across the capacitor bank and converts the voltage into a digital code, the capacitor bank is in a configurable second connection state.

9. The time-to-digital converter according to claim 8, wherein
the first capacitor bank and the second capacitor bank have the same number of capacitors, and the capacitors in the two banks are paired one by one;
the analog-to-digital conversion module further comprises a first capacitor switching switch group and a second capacitor switching switch group, wherein first ends of the capacitors in the first capacitor bank are connected to each other, and a second end of one of the capacitors is connected to a power supply voltage, and the second ends of the other capacitors are controllably connected to the power supply voltage or ground via the corresponding switches in the first capacitor switching switch group respectively, and the first ends of the capacitors in the second capacitor bank are connected to each other, and the second end of one of the capacitors is connected to the power supply voltage, and the second ends of the other capacitors are controllably connected to the power supply voltage or ground via the corresponding switches in the second capacitor switching switch group respectively;
the analog-to-digital conversion module further comprises a switch control module, configured to use a successive approximation algorithm to generate capacitor switching signals for controlling each pair of switches in the first and second capacitor switching switch groups; and
the analog-to-digital conversion module further comprises a comparator, the positive input terminal of the comparator is connected to the first ends of the capacitors in the first capacitor bank, the negative input terminal of the comparator is connected to the first ends of the capacitors in the second capacitor bank, and the output terminal of the comparator outputs a digital code, wherein the comparator is configured to output multiple digital codes constituting the multi-bit digital code by comparisons under the control of the capacitor switching signals generated based on the successive approximation algorithm.

10. The time-to-digital converter according to claim 9, wherein
in the first connection state, the second end of each capacitor in the first capacitor bank is connected in parallel to the power supply voltage, the first end is connected in parallel to the first end of the first current source, the second end of each capacitor in the second capacitor bank is connected in parallel to the power supply voltage, and the first end is connected in parallel to the second end of the second current source;
in the configurable second connection state, through the control of the first capacitor switching switch bank and the second capacitor switching switch bank by the capacitor switching signals, the first capacitor bank is divided into a first capacitor subgroup and a second capacitor subgroup, and the first capacitor subgroup and the second capacitor subgroup are connected in series between the power supply voltage and the ground, the second capacitor bank is divided into a third capacitor subgroup and a fourth capacitor subgroup, and the third capacitor subgroup and the fourth capacitor subgroup are connected in series between the power supply voltage and the ground.

11. The time-to-digital converter according to claim 1, wherein the first signal is a feedback pulse signal of a phase-locked loop circuit, and the second signal is a reference pulse signal;
the time difference corresponds to the phase difference between the first signal and the second signal.

12. A phase-locked loop circuit, comprising:
the time-to-digital converter according to claim 1, configured to detect a time difference between a first signal and a second signal and output a corresponding multi-bit digital code, wherein the first signal is a feedback pulse signal of a phase-locked loop circuit, and the second signal is a reference pulse signal;
a digital-controlled oscillator, configured to adjust the frequency of an output clock signal according to the multi-bit digital code; and
a feedback path, configured to generate the feedback pulse signal based on the output clock signal.

13. The phase-locked loop circuit according to claim 12, further comprising:
a loop filter, connected between the time-to-digital converter and the digital-controlled oscillator, configured to filter the multi-bit digital code;
wherein the feedback path comprises a frequency divider, configured to generate the feedback pulse signal after dividing the frequency of the output clock signal.
